(19) United States
(12) Patent Application Publication
(10) Pub. No.: US 2026/0107840 A1
(43) Pub. Date: Apr. 16, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Dawoon JUNG, Suwon-si (KR); Haseob SEONG, Suwon-si (KR)

(73) Assignee: Samsung Electronics Co., Ltd., Suwon-si (KR)

(21) Appl. No.: 19/318,598

(22) Filed: Sep. 4, 2025

(30) Foreign Application Priority Data
Oct. 11, 2024 (KR) 10-2024-0138856

(51) Int. Cl. H01L 25/065; H01L 23/00; H01L 23/31; H01L 23/48

(52) U.S. Cl. CPC H10W 90/00; H10W 20/20; H10W 74/131; H10W 72/942; H10W 72/944; H10W 80/743; H10W 90/28; H10W 90/297; H10W 90/792

(57) ABSTRACT

A semiconductor package may include a base chip, a semiconductor chip stack including a plurality of semiconductor chips sequentially stacked on the base chip, a plurality of connection bumps below the base chip, and an encapsulant covering a side surface of the first semiconductor chip and side surfaces of each of the plurality of second semiconductor chips on the base chip, wherein, on at least one side of the semiconductor chip stack, the encapsulant includes a portion in which a width thereof in a horizontal direction increases as the encapsulant being away from the base chip in a vertical direction.

### CROSS-REFERENCE TO RELATED APPLICATION(S)

This application claims benefit of priority to Korean Patent Application No. 10-2024-0138856 filed on Oct. 11, 2024, in the Korean Intellectual Property Office, the disclosure of which is incorporated herein by reference in its entirety.

### BACKGROUND

The present disclosure relates to semiconductor packages and methods of manufacturing the same.

A semiconductor device mounted on an electronic device needs miniaturization and/or the implementation of higher performance and/or high capacity. In order to implement the same, a semiconductor package for interconnecting semiconductor chips stacked in a vertical direction using a through-electrode (e.g., a through-silicon via) has been developed.

### SUMMARY

Some example embodiments of the present disclosure provide semiconductor packages having improved reliability.

According to an example embodiment of the present disclosure, a semiconductor package includes a base chip including lower connection terminals, upper connection terminals and through-electrodes, the lower connection terminals and upper connection terminals being opposite to each other, the through-electrodes electrically connecting the lower connection terminals and the upper connection terminals, and a semiconductor chip stack including a plurality of semiconductor chips sequentially stacked on the base chip in a first direction, wherein the plurality of semiconductor chips of the semiconductor chip stack include a first semiconductor chip on the base chip, the first semiconductor chip including first lower pads,, first upper pads, and first through-vias, the first lower pads and the first upper pads being opposite to each other, the first through-vias electrically connecting the first lower pads and the first upper pads, and at least one second semiconductor chip on the first semiconductor chip, the at least one second semiconductor chip including second lower pads, second upper pads and second through-vias, the second lower pads and the second upper pads being opposite to each other, the second through-vias electrically connecting the second lower pads and the second upper pads, and a plurality of connection bumps below the base chip and electrically connected to the lower connection terminals, the first lower pads of the first semiconductor chip are in contact with corresponding ones of the upper connection terminals of the base chip that are adjacent to the first lower pads of the first semiconductor chip in the first direction, respectively, the first upper pads of the first semiconductor chip are in contact with corresponding ones of the second lower pads of the at least one second semiconductor chip that are adjacent to the first upper pads of the first semiconductor chip in the first direction, a side surface of the first semiconductor chip includes a first portion extending from a lower surface of the first semiconductor chip at a first inclination, and a second portion extending from the first portion to an upper surface of the first semiconductor chip at a second inclination less than the first inclination, and a side surface of the at least one second semiconductor chip includes a third portion extending from a lower surface of the at least one second semiconductor chip at a third inclination, and a fourth portion extending from the third portion to an upper surface of the at least one second semiconductor chip at a fourth inclination, less than the third inclination.

According to an example embodiment of the present disclosure, a semiconductor package includes a base chip including lower connection terminals, upper connection terminals and through-electrodes, the lower connection terminals and the upper connection terminals being opposite to each other, the through-electrodes electrically connecting the lower connection terminals and the upper connection terminals, a first semiconductor chip on the base chip, the first semiconductor chip including a first semiconductor substrate,, first lower pads, first upper pads, a first passivation layer and first through-vias, the first lower pads in a lower portion of the first semiconductor substrate, the first upper pads in an upper portion of the first semiconductor substrate, the first passivation layer surrounding the first upper pads in the upper portion of the first semiconductor substrate, the first through-vias penetrating through the first semiconductor substrate and electrically connecting the first lower pads and the first upper pads, a plurality of second semiconductor chips sequentially stacked on the first semiconductor chip in a first direction, each of the plurality of second semiconductor chips including a second semiconductor substrate, second lower pads, second upper pads, a second passivation layer and second through-vias, the second lower pads in a lower portion of the second semiconductor substrate, the second upper pads in an upper portion of the second semiconductor substrate, the second passivation layer surrounding the second upper pads in the upper portion of the second semiconductor substrate, the second through-vias penetrating through the second semiconductor substrate and electrically connecting the second lower pads and the second upper pads, and a plurality of connection bumps below the base chip and electrically connected to the lower connection terminals, wherein the first lower pads of the first semiconductor chip are in contact with corresponding ones of the upper connection terminals of the base chip, respectively, the first upper pads of the first semiconductor chip are in contact with corresponding ones of the second lower pads of a second semiconductor chip that is adjacent to the first semiconductor chip in the first direction, among the plurality of second semiconductor chips, respectively, the second upper pads of each of the plurality of second semiconductor chips are in contact with corresponding ones of the second lower pads of an adjacent second semiconductor chip, among the plurality of second semiconductor chips, in the first direction, respectively, a width of the first semiconductor substrate of the first semiconductor chip in a horizontal direction is greater than a width of the second semiconductor substrate of each of the plurality of second semiconductor chips in the horizontal direction, and the second semiconductor substrate of each of the plurality of second semiconductor chips has a width in the horizontal direction that decreases as the second semiconductor substrate being away from the base chip in the first direction.

According to an example embodiment of the present disclosure, a semiconductor package includes a base chip including lower connection terminals, upper connection terminals, and through-electrodes, the lower connection terminals and the upper connection terminals being opposite to each other, the through-electrodes electrically connecting the lower connection terminals and the upper connection terminals, and a semiconductor chip stack including a plurality of semiconductor chips sequentially stacked on the base chip in a first direction, wherein the plurality of semiconductor chips of the semiconductor chip stack include a first semiconductor chip on the base chip, the first semiconductor chip including first lower pads, first upper pads and first through-vias, the first lower pads and first upper pads being opposite to each other, the first through-vias electrically connecting the first lower pads and the first upper pads, and a plurality of second semiconductor chips sequentially stacked on the first semiconductor chip in the first direction, each of the plurality of second semiconductor chips including second lower pads, second upper pads and second through-vias, the second lower pads and second upper pads being opposite to each other, the second through-vias electrically connecting the second lower pads and the second upper pads, a plurality of connection bumps below the base chip and electrically connected to the lower connection terminals, an encapsulant covering a side surface of the first semiconductor chip and side surfaces of each of the plurality of second semiconductor chips on the base chip, and on at least one side of the semiconductor chip stack, the encapsulant includes a portion in which a width thereof in a horizontal direction increases as the encapsulant being away from the base chip in the first direction.

According to an example embodiment of the present disclosure, a method of manufacturing a semiconductor package includes providing a first semiconductor chip on a base chip, the base chip including a substrate, lower connection terminals on a lower surface of the substrate, upper connection terminals on an upper surface of the substrate, and through-vias electrically connecting the lower connection terminals and the upper connection terminals, perform a first planarization process on an upper surface of the first semiconductor chip, providing at least one second semiconductor chip on the first semiconductor chip, perform a second planarization process on an upper surface of the at least one second semiconductor chip, providing a third semiconductor chip on an upper surface of an uppermost chip of the at least one second semiconductor chip, and forming an encapsulant to cover the first semiconductor chip, the at least one second semiconductor chip, and the third semiconductor chip.

The providing of the first semiconductor chip on the base chip may include directly bonding the first semiconductor chip to the base chip by intermetallic bonding and inter-dielectric bonding.

The providing of the at least one second semiconductor chip on the first semiconductor chip may include directly bonding the at least one second semiconductor chip to the first semiconductor chip by intermetallic bonding and inter-dielectric bonding.

According to some example embodiments of the present disclosure, semiconductor packages having improved reliability and/or methods of manufacturing the same may be provided.

According to some example embodiments of the present disclosure, an inclination surface on an edge of each side surface of a plurality of semiconductor chips stacked in multiple stages may be formed, thereby providing semiconductor packages having improved quality and/or reliability of a bonding surface.

Advantages and effects of the present application are not limited to the foregoing content and may be more easily understood in the process of describing some specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor package according to an example embodiment;

FIG. 2 is a cross-sectional view of a semiconductor package taken along line I-I′ of FIG. 1;

FIG. 3 is a partially enlarged view illustrating region ‘A’ of FIG. 2;

FIG. 4 is a partially enlarged view illustrating region ‘B’ of FIG. 2;

FIG. 5 is a partially enlarged view illustrating region ‘C’ of FIG. 2;

FIGS. 6A to 6C are partially enlarged views of a semiconductor package according to some example embodiments;

FIG. 7A is a plan view illustrating a semiconductor package according to an example embodiment;

FIG. 7B is a cross-sectional view of a semiconductor package taken along line II-II′ of FIG. 7A;

FIGS. 8 to 12 are cross-sectional views illustrating a method of manufacturing a semiconductor package according to an example embodiment of the present disclosure, according to a process order; and

FIGS. 13A and 13B are graphs illustrating surface topologies of each of a plurality of semiconductor chips before and after a planarization process.

### DETAILED DESCRIPTION

Hereinafter, the terms ‘above,’ ‘upper portion,’ ‘upper surface,’ ‘below’, ‘lower portion,’ ‘lower surface,’ ‘side surface,’ ‘upper end,’ ‘lower end,’ and the like, may be understood as being indicated based on the drawing, except that they are indicated by drawing references and referred to separately. The terms “upper,” “intermediate,” “lower”, and the like, may be replaced with other terms, such as “first,” “second,” and “third,” and used to describe components of the specification. The terms “first,” “second,” and “third” may be used to describe various components, but the components are not limited by the terms, and the “first component” may be termed the “second component.”

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, some example embodiments of the present disclosure will be described with reference to the accompanying drawings.

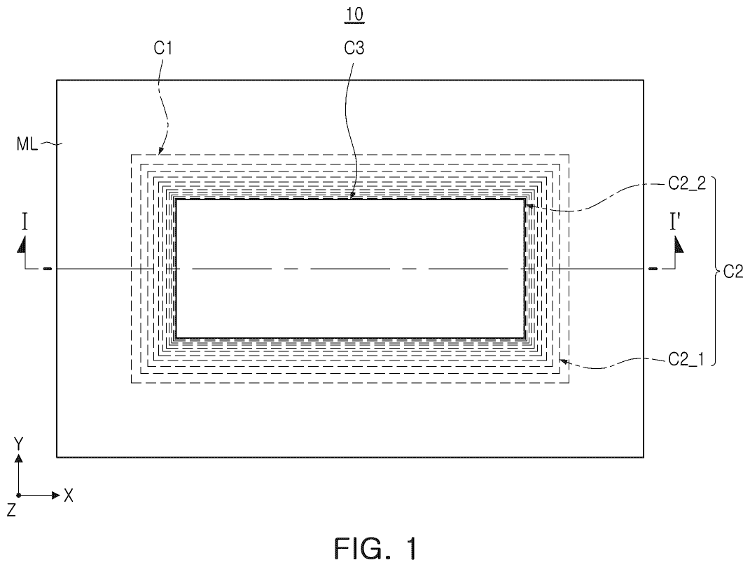

FIG. 1 is a plan view illustrating a semiconductor package according to an example embodiment.

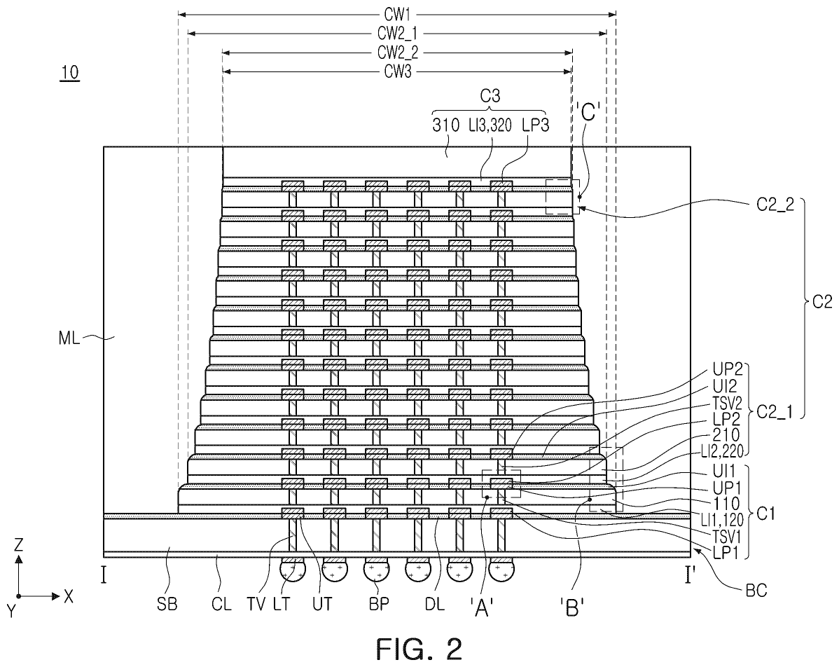

FIG. 2 is a cross-sectional view of a semiconductor package taken along line I-I′ of FIG. 1.

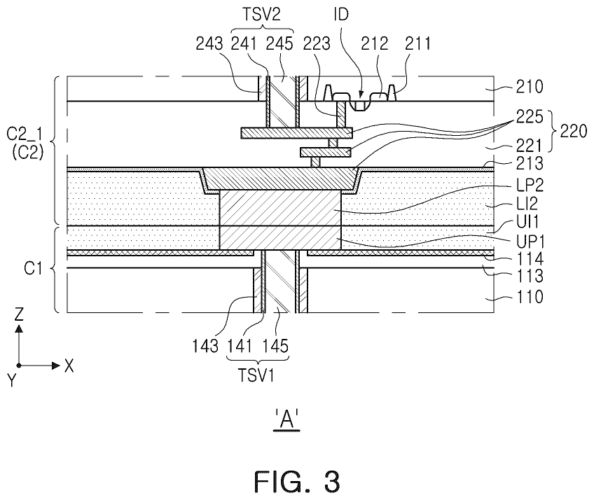

FIG. 3 is a partially enlarged view illustrating region ‘A’ of FIG. 2.

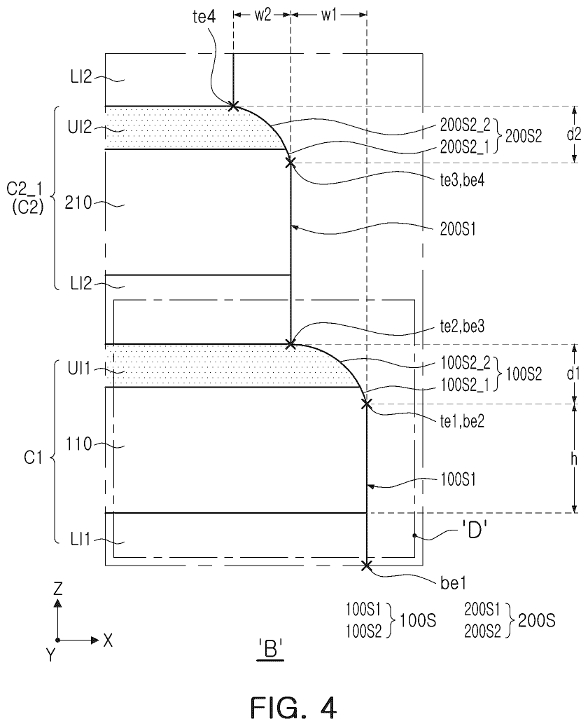

FIG. 4 is a partially enlarged view illustrating region ‘B’ of FIG. 2.

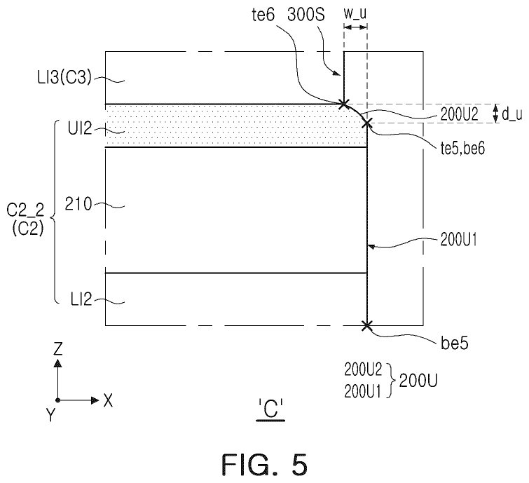

FIG. 5 is a partially enlarged view illustrating region ‘C’ of FIG. 2.

Referring to FIGS. 1 to 5, a semiconductor package 10 of an example embodiment may include a plurality of semiconductor chips C1, C2 and C3 on a base chip BC. According to an example embodiment, the plurality of semiconductor chips C1, C2 and C3 may be referred to as a semiconductor chip stack. According to an example embodiment, the semiconductor package 10 may further include an encapsulant ML and/or a plurality of connection bumps BP.

The plurality of semiconductor chips C1, C2 and C3 may be formed of or include memory chips or memory devices for storing or outputting data based on address commands and control commands received from the base chip BC. For example, the plurality of semiconductor chips C1, C2 and C3 may include volatile memory devices such as DRAM or SRAM, or nonvolatile memory devices such as PRAM, MRAM, FeRAM, or RRAM. Among the plurality of semiconductor chips C1, C2 and C3, an uppermost third semiconductor chip C3 (hereinafter, “third semiconductor chip”) does not include a through-electrode and a one surface (e.g., a rear surface) thereof may be exposed from the encapsulant ML, but example embodiments of the present disclosure is not limited thereto.

The plurality of semiconductor chips C1, C2 and C3 may include a first semiconductor chip C1, at least one second semiconductor chip C2, and a third semiconductor chip C3, which are sequentially stacked on a base chip BC in a first direction (e.g., vertical direction or Z-direction).

The base chip BC may include a substrate SB, lower connection terminals LT and upper connection terminals UT opposite to each other, a device layer CL, and through-vias TV electrically connecting the lower connection terminals LT and the upper connection terminals UT. The base chip BC may further include an upper protection layer DL surrounding the upper connection terminals UT.

The base chip BC may be, for example, a buffer chip including a plurality of logic devices and/or a plurality of memory devices in the device layer CL. Accordingly, the base chip BC may transmit signals from the plurality of semiconductor chips C1, C2 and C3 stacked in an upper portion thereof to the outside, and may also transmit signals and power from the outside to the plurality of semiconductor chips C1, C2 and C3. The base chip BC may perform both a logic function and a memory function through the logic devices and the memory devices, but according to an example embodiment, the base chip BC may perform only the logic function by including only the logic devices.

The substrate SB may include, for example, a semiconductor element such as silicon or germanium (Ge), or a compound semiconductor such as silicon carbide (SiC), gallium arsenide (GaAs), indium arsenide (InAs), or indium phosphide (InP). The substrate SB may have a silicon on insulator (SOI) structure. The substrate SB may include a conductive region, such as a doped well or a doped structure. The substrate SB may include various device isolation structures, such as a shallow trench isolation (STI) structure.

The upper connection terminals UT may be disposed on an upper surface of the substrate SB (or in an upper surface of the base chip BC). The upper connection terminals UT may include a conductive material. The upper connection terminals UT may include, for example, copper (Cu). The lower connection terminals LT may be disposed on a lower surface of the device layer CL (or in a lower portion of the base chip BC). The lower connection terminals LT may include the same material as the upper connection terminals UT, but example embodiments of the present disclosure is not limited thereto. For example, the lower connection terminals LT may include at least one of aluminum (Al), nickel (Ni), tungsten (W), platinum (Pt), or gold (Au).

The upper protection layer DL may be formed on the upper surface of the substrate SB and can protect the substrate SB. The upper protection layer DL may be formed of or include an insulating layer such as a silicon oxide film, a silicon nitride film, or a silicon oxynitride film, but the material of the upper protection layer DL is not limited to the above-described materials. For example, the upper protection layer DL may be formed of or include a polymer such as Polyimide (PI) or Photosensitive polyimide (PSPI). Although not illustrated in the drawing, a lower protection layer may be further formed on a lower surface of the device layer CL.

The device layer CL may be disposed on a lower surface of the substrate SB and may include various types of devices. For example, the device layer CL may include field effect transistors (FET) such as planar Field Effect Transistors (FET) or FinFET, a flash memory, memory devices such as a Dynamic Random Access Memory (DRAM), a Static Random Access Memory (SRAM), an Electrically Erasable Programmable Read-Only Memory (EEPROM), a Phase-change Random Access Memory (PRAM), a Magnetoresistive Random Access Memory (MRAM), a Ferroelectric Random Access Memory (FeRAM) and a Resistive Random Access Memory (RRAM), logic devices such as AND, OR and NOT, and various active devices and/or passive devices such as system Large Scale Integration (LSI), a CMOS Imaging Sensor (CIS), and a Micro-Electro-Mechanical System (MEMS).

The device layer CL may include an interlayer insulation layer (not illustrated) and a multilayer interconnection layer (not illustrated) on the above-described devices. The interlayer insulating layer (not illustrated) may include silicon oxide or silicon nitride. The multilayer interconnection layer (not illustrated) may include multilayer interconnection lines and/or vertical contacts. The multilayer interconnection layer (not illustrated) may connect devices of the device layer CL to each other, may connect the devices to a conductive region of the substrate SB, or may connect the devices to the lower connection terminals LT.

The through-vias TV may penetrate through the substrate SB in the vertical direction (Z-direction) and may provide an electrical path for connecting the lower connection terminals LT and the upper connection terminals UT. The through-vias TV may be electrically connected to the plurality of semiconductor chips C1, C2 and C3. The through-vias TV may include a conductive plug and a barrier film surrounding the conductive plug. The conductive plug may include a metallic material, such as tungsten (W), titanium (Ti), aluminum (Al), or copper (Cu). The conductive plug may be formed in a plating process, a PVD process, or a CVD process. The barrier film may include titanium (Ti), titanium nitride (TiN), tantalum (Ta), or tantalum nitride (TaN), and may be formed in a plating process, a PVD process, or a CVD process. A side insulating film (not illustrated) including an insulating material (e.g., High Aspect Ratio Process (HARP) oxide) such as silicon oxide, silicon nitride, or silicon oxynitride may be formed between a side surface of the through-vias TV and the substrate SB.

The connection bumps BP may be disposed below the base chip BC. The connection bumps BP may be electrically connected to the plurality of semiconductor chips C1, C2 and C3 through the through-vias TV. The connection bumps BP may include, for example, tin (Sn) or alloys including tin (Sn) (for example, Sn—Ag—Cu). According to an example embodiment, the connection bumps BP may have a form in which a metal pillar and a solder ball are combined. The connection bumps BP may be electrically connected to an external device such as a module substrate or a system board. The base chip BC may have a width greater than widths of each of the plurality of semiconductor chips C1, C2 and C3 in a horizontal direction (e.g., X-direction and/or Y-direction). Although not illustrated, at least some of the connection bumps BP and at least some of the lower connection terminals LT may be disposed in a position that does not overlap the plurality of semiconductor chips C1, C2 and C3 in the vertical direction (Z-direction).

The first semiconductor chip C1 may be disposed on the base chip BC, and may include a first substrate 110, a first circuit layer 120, first lower pads LP1 and first upper pads UP1, opposite to each other, and first through-electrodes TSV1 electrically connecting the first lower pads LP1 and the first upper pads UP1. According to an example embodiment, the first semiconductor chip C1 may further include a first upper insulating layer UI1 surrounding the first upper pads UP1. According to an example embodiment, the first upper insulating layer may be referred to as a first passivation layer. According to an example embodiment, the first semiconductor chip C1 may further include a first lower insulating layer LI1 surrounding the first lower pads LP1.

The first substrate 110 may include, for example, a semiconductor element, such as silicon or germanium (Ge), or may include a compound semiconductor, such as silicon carbide (SiC), gallium arsenide (GaAs), indium arsenide (InAs), or indium phosphide (InP). The first substrate 110 may have a silicon on insulator (SOI) structure. The first substrate 110 may include a conductive region, such as a well doped with impurities, or a structure doped with impurities. The first substrate 110 may include various device isolation structures, such as a shallow trench isolation (STI) structure. In an example embodiment, the first substrate 110 may be referred to as a first semiconductor substrate.

The first upper pads UP1 may be disposed on an upper surface of the first substrate 110 (or in an upper portion of the first semiconductor chip C1). The first upper pads UP1 may include a conductive material. The first upper pads UP1 may include, for example, copper (Cu). The first lower pads LP1 may be disposed on a lower surface of the first lower insulating layer LI1 (or in a lower portion of the first semiconductor chip C1). The first lower pads LP1 may include a material identical to or similar to the first upper pads UP1.

The first upper insulating layer UI1 may be formed on the upper surface of the first substrate 110 and may protect the first substrate 110. The first upper insulating layer UI1 may surround side surfaces of the first upper pads UP1. The first upper insulating layer UI1 may be formed as an insulating layer such as a silicon oxide film, a silicon nitride film, or a silicon oxynitride film, but the material of the first upper insulating layer UI1 is not limited to the above-described materials. For example, the first upper insulating layer UI1 may be formed of or include a polymer such as Polyimide (PI) or Photosensitive polyimide (PSPI).

The first lower insulating layer LI1 may be formed in a lower portion of the first substrate 110. The first lower insulating layer LI1 may surround side surfaces of the first lower pads LP1. The first lower insulating layer LI1 may include, for example, silicon oxide (SiO) or silicon carbonitride (SiCN).

A first circuit layer 120 may be formed between the first substrate 110 and the first lower insulating layer LI1. The first circuit layer 120 may be substantially identical to or similar to a second circuit layer 220 to be described with reference to FIG. 3.

The through-electrodes TSV1 may penetrate through the first substrate 110 in the vertical direction (Z-direction), and may provide an electrical path for connecting the first lower pads LP1 and the first upper pads UP1. The through-electrodes TSV1 may include a via plug 145 and a side barrier layer 141 surrounding a side surface thereof. The via plug 145 may include, for example, tungsten (W), titanium (Ti), aluminum (Al), or copper (Cu), and may be formed in a plating process, a PVD process, or a CVD process. The side barrier layer 141 may include titanium (Ti), titanium nitride (TiN), tantalum (Ta), or tantalum nitride (TaN), and may be formed in the plating process, the PVD process, or the CVD process. A side insulating film 143 including an insulating material (e.g., HARP oxide) such as silicon oxide, silicon nitride, or silicon oxynitride may be formed between the side barrier layer 141 and the first substrate 110.

The through-electrodes TSV1 may penetrate through an insulating protection layer 113 formed on a rear surface of the first substrate 110. The insulating protection layer 113 may include, for example, silicon oxide (SiO), silicon nitride (SiN), silicon carbide (SiC), silicon oxynitride (SiON), or silicon carbonitride (SiCN). A buffer film 114 such as a polishing stop layer or a barrier may be disposed on the insulating protection layer 113. For example, the buffer film may include silicon nitride, silicon carbide, silicon oxynitride, or silicon carbonitride (see FIG. 3).

The first semiconductor chip C1 and the base chip BC may be bonded and coupled to each other by intermetallic bonding and inter-dielectric bonding.

For example, each of the first lower pads LP1 of the first semiconductor chip C1 and each of the upper connection terminals UT of the base chip BC may be in contact with each other. The first lower insulating layer LI1 of the first semiconductor chip C1 and the upper protection layer DL of the base chip BC may be in contact with each other.

The first semiconductor chip C1 may have a first side surface 100S extending from an edge of the lower surface of the first lower insulating layer LI1 to an edge of an upper surface of the first upper insulating layer UI1 (see FIG. 4).

The first side surface 100S may be defined as including a plurality of portions 100S1 and 100S2. The plurality of portions 100S1 and 100S2 may include a first portion 100S1 and a second portion 100S2 connected to each other.

The first portion 100S1 has a first lower end be1 connected to a lower surface of the first semiconductor chip C1, and a first upper end te1 connected to the second portion 100S2, and may extend from the first lower end be1 to the first upper end te1 at a constant first inclination. The first upper end te1 may be formed on a side surface of the first substrate 110. A height h of a point at which the first upper end te1 is formed from a lower surface of the first substrate 110 may be at least ½ of a thickness of the first substrate 110. Accordingly, the first upper end te1 may be formed in an upper region of the side surface of the first substrate 110, and the first portion 100S1 may be defined as a portion formed in a lower region of the first side surface 100S.

The second portion 100S2 may have a second lower end be2 connected to the first upper end te1, and a second upper end te2 connected to an upper surface of the first semiconductor chip C1, and may extend from the second lower end be2 to the second upper end te2 at a reduced second inclination. In another aspect, a magnitude of an absolute value of the second inclination may decrease from the second lower end be2 to the second upper end te2.

A magnitude of an absolute value of an average of the second inclination of the second portion 100S2 may be less than a magnitude of an absolute value of an average of the first inclination of the first portion 100S1. Here, the average of the first inclinations may be referred to as a first mean inclination, and an average of the second inclinations may be referred to as the second mean inclination. Here, each of the first and second mean inclinations may be defined as a ratio of a depth in a vertical direction (e.g., Z-direction) to a width in a horizontal direction (e.g., X-direction and/or Y-direction). For example, the second mean inclination may be defined as a ratio of a depth d1 in the vertical direction to a width w1 in the horizontal direction.

In an example embodiment, the width w1 of the second portion 100S2 in the horizontal direction (e.g., X-direction and/or Y-direction) may be greater than the depth d1 in the vertical direction (e.g., Z-direction). The width w1 may be, for example, approximately 500 um. In an example embodiment, the width w1 may be, for example, approximately 100 um to approximately 500 um. In an example embodiment, the width w1 may be, for example, approximately 200 um to approximately 400 um. In an example embodiment, the width w1 may be, for example, approximately 300 um to approximately 400 um. The depth d1 may be, for example, approximately 10 um. In an example embodiment, the depth d1 may range, for example, from approximately 1 um to approximately 10 um. In an example embodiment, the depth d1 may be greater than a thickness of the first upper insulating layer UI1 in the vertical direction.

The second portion 100S2 may be defined as including a plurality of portions 100S2_1 and 100S2_2. The plurality of portions 100S2_1 and 100S2_2 may include a first portion 100S2_1 and a second portion 100S2_2 connected to each other.

The first portion 100S2_1 may be a portion formed on the side surface of the first substrate 110, and the second portion 100S2_2 may be a portion formed on a side surface of the first upper insulating layer UI1. For example, the first portion 100S2_1 may be a portion formed on an upper region of the side surface of the first substrate 110. A depth of the first portion 100S2_1 in the vertical direction (e.g., in the Z-direction) may be substantially the same as or less than a depth of the second portion 100S2_2 in the vertical direction.

In another aspect, the first semiconductor chip C1 may be defined as including a plurality of inclination surfaces. The first semiconductor chip C1 may include a first inclination surface formed in the lower region of the first side surface 100S, a second inclination surface connected to the first inclination surface and formed in an upper region of the side surface of the first substrate 110, and a third inclination surface connected to the second inclination surface and formed on the side surface of the first upper insulating layer UI1. Here, the first inclination surface may correspond to the first portion 100S1, the second inclination surface may correspond to the first portion 100S2_1 of the second portion 100S2, and the third inclination surface may correspond to the second portion 100S2_2 of the second portion 100S2. According to an example embodiment, the second and third inclination surfaces may be referred to as curved surface portions. A magnitude of an absolute value of a mean inclination of the second inclination surface may be less than a magnitude of an absolute value of a mean inclination of the first inclination surface, and a magnitude of an absolute value of a mean inclination of the third inclination surface may be less than the magnitude of the absolute value of the mean inclination of the second inclination surface.

At least one second semiconductor chip C2 may be disposed on the first semiconductor chip C1. At least one second semiconductor chip C2 may include a plurality of second semiconductor chips sequentially stacked in the first direction (e.g., Z-direction) on the first semiconductor chip C1. The plurality of second semiconductor chips C2 may include a lowermost second semiconductor chip (hereinafter, a second-first semiconductor chip C2_1) and an uppermost second semiconductor chip (hereinafter, a second-second semiconductor chip C2_2).

Each of the plurality of second semiconductor chips C2 may include a second substrate 210, a second circuit layer 220, second lower pads LP2 and second upper pads UP2 opposite to each other, and second through-electrodes TSV2 electrically connecting the second lower pads LP2 and the second upper pads UP2. According to an example embodiment, each of the plurality of second semiconductor chips C2 may further include a second upper insulating layer UI2 surrounding the second upper pads UP2. According to an example embodiment, the second upper insulating layer may be referred to as a second passivation layer. According to an example embodiment, each of the plurality of second semiconductor chips C2 may further include a circuit layer 220 and a second lower insulating layer LI2 surrounding the second lower pads LP2.

The second substrate 210 may be substantially identical to or similar to the first substrate 110. In an example embodiment, the second substrate 210 may be referred to as a second semiconductor substrate.

The second upper pads UP2 may be disposed on an upper surface of the second substrate 210 (or in upper portions of each of the plurality of second semiconductor chips C2). The second upper pads UP2 may include a conductive material. The second upper pads UP2 may include, for example, copper (Cu). The second lower pads LP2 may be disposed on a lower surface of the second lower insulating layer LI2 (or in lower portions of each of the plurality of second semiconductor chips C2). The second lower pads LP2 may include a material identical to or similar to the second upper pads UP2.

The second upper insulating layer UI2 may be formed on the upper surface of the second substrate 210 and may protect the second substrate 210. The second upper insulating layer UI2 may surround side surfaces of the second upper pads UP2. The second upper insulating layer UI2 may be formed of or include an insulating layer such as a silicon oxide film, a silicon nitride film, or a silicon oxynitride film, but the material of the second upper insulating layer UI2 is not limited to the above-described materials. For example, the second upper insulating layer UI2 may be formed of or include a polymer such as Polyimide (PI) or Photosensitive polyimide (PSPI).

The second lower insulating layer LI2 may be formed in a lower portion of the second substrate 210. The second lower insulating layer LI2 may surround side surfaces of the second lower pads LP2. The second lower insulating layer LI2 may include, for example, silicon oxide (SiO) or silicon carbonitride (SiCN).

The second circuit layer 220 may be disposed on a front surface (e.g., a lower surface) of the second substrate 210 on which a conductive region 212 is formed. The second circuit layer 220 may include individual devices ID, an interlayer insulating layer 221, and an interconnection structure 225.

The individual devices ID may be disposed on the front surface of the second substrate 210. The individual devices ID may include, for example, FET such as planar FETs or FinFET, memory devices such as a flash memory, DRAM, SRAM, EEPROM, PRAM, MRAM, FeRAM or RRAM, logic devices such as AND, OR or NOT, and various active devices and/or passive devices such as system LSI, CIS, or MEMS.

The interlayer insulating layer 221 may cover the individual devices ID and the interconnection structure 225, thus electrically isolating the individual devices ID disposed on the second substrate 210. The interlayer insulating layer 221 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. At least a partial region of the interlayer insulating layer 221 surrounding the interconnection structure 225 may be formed of or include a low-κ dielectric layer. The interlayer insulating layer 221 may be formed using a chemical vapor deposition (CVD), a flowable-CVD process, or a spin coating process. Depending on the process, boundaries between the interlayer insulating layer 221 and the second lower insulating layer LI2 may not be clearly distinguished.

The interconnection structure 225 may be formed as a multilayer structure including a plurality of interconnection patterns and a plurality of vias formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film (not illustrated) including titanium (Ti), titanium nitride (TiN), tantalum (Ta), or tantalum nitride (TaN) may be disposed between the interconnection patterns or/and the vias and the interlayer insulating layer 221. The interconnection structure 225 may be electrically connected to the conductive region 212 and/or individual devices ID by an interconnection portion 223 (e.g., a contact plug).

The through-electrodes TSV2 may penetrate through the second substrate 110 in the vertical direction (Z-direction), and may provide an electrical path for connecting the second lower pads LP2 and the second upper pads UP2. The through-electrodes TSV2 may include a via plug 245 and a side barrier layer 241 surrounding a side surface thereof. The via plug 245 may include, for example, tungsten (W), titanium (Ti), aluminum (Al), or copper (Cu), and may be formed in the plating process, the PVD process, or the CVD process. The side barrier layer 241 may include titanium (Ti), titanium nitride (TiN), tantalum (Ta), or tantalum nitride (TaN), and may be formed in the plating process, the PVD process, or the CVD process. A side insulating film 243 including an insulating material such as silicon oxide, silicon nitride, or silicon oxynitride (e.g., HARP oxide) may be formed between the side barrier layer 241 and the second substrate 210.

A lowermost second-first semiconductor chip C2_1 and the first semiconductor chip C1 may be bonded and coupled to each other by intermetallic bonding and inter-dielectric bonding.

For example, each of the second lower pads LP2 of the second-first semiconductor chip C2_1 and each of the first upper pads UP1 of the first semiconductor chip C1 may be in contact with each other. The second lower insulating layer LI2 of the second-first semiconductor chip C2_1 and the first upper insulating layer UI1 of the first semiconductor chip C1 may be in contact with each other.

Among the plurality of second semiconductor chips C2, the second semiconductor chips adjacent to each other in the first direction (e.g., the Z-direction) may be bonded and coupled to each other by intermetallic bonding and inter-dielectric bonding. The second upper pads UP2 of each of the plurality of second semiconductor chips C2 may be in contact with the second lower pads LP2 of a corresponding one of the plurality of second semiconductor chips C2 adjacent to each other in the first direction. Second insulating layers LI2 and UI2 of each of the plurality of second semiconductor chips C2 may be in contact with second insulating layers LI2 and UI2 of a corresponding one of the plurality of second semiconductor chips C2 adjacent to each other in the first direction.

Each of the plurality of second semiconductor chips C2 may have a second side surface 200S extending from an edge of the lower surface of the second lower insulating layer LI2 to an edge of the upper surface of the second upper insulating layer UI2 (see FIG. 4).

The second side surface 200S may be defined as including a plurality of portions 200S1 and 200S2. The plurality of portions 200S1 and 200S2 may include a third portion 200S1 and a fourth portion 200S2 connected to each other.

The third portion 200S1 may have a third lower end be3 connected to a lower surface of the second semiconductor chip C2, and a third upper end te3 connected to the fourth portion 100S2, and may extend from the third lower end be3 to the third upper end te3 at a constant third inclination. The third upper end te3 may be formed on a side surface of the second substrate 210. A height of a point at which the third upper end te3 is formed from a lower surface of the second substrate 210 may be ½ or more of a thickness of the second substrate 210. Accordingly, the third upper end te3 may be formed in an upper region of the side surface of the second substrate 210, and the third portion 200S1 may be defined as a portion formed in a lower region of the second side surface 200S.

The fourth portion 200S2 may have a fourth lower end be4 connected to the third upper end te3, and a fourth upper end te4 connected to an upper surface of the second semiconductor chip C2, and may extend from the fourth lower end be4 to the fourth upper end te4 at a reduced fourth inclination. In another aspect, a magnitude of an absolute value of the fourth inclination may decrease from the fourth lower end be4 to the fourth upper end te4.

The magnitude of the absolute value of the average of the fourth inclination of the fourth portion 200S2 may be less than a magnitude of an absolute value of an average of the third inclination of the third portion 200S1. Similarly to that described above, the average of the third inclination may be referred to as a third mean inclination, and the average of the fourth inclination may be referred to as a fourth mean inclination. Each of the third and fourth mean inclinations may be defined as a ratio of a depth in the vertical direction (e.g., Z-direction) to a width in the horizontal direction (e.g., X-direction and/or Y-direction). For example, the fourth mean inclination may be defined as a ratio of a depth d2 in a vertical direction to a width w2 in a horizontal direction.

In an example embodiment, the width w2 of the fourth portion 200S2 in the horizontal direction (e.g., X-direction and/or Y-direction) may be less than the width w1 of the second portion 100S2. In an example embodiment, the depth d2 in the vertical direction (e.g., Z-direction) of the fourth portion 200S2 may be less than the width w1 of the second portion 100S2. In another aspect, an absolute value of the fourth mean inclination may be greater than an absolute value of the second mean inclination.

In an example embodiment, the width w2 in the horizontal direction (e.g., X-direction and/or Y-direction) may be greater than the depth d2 of the fourth portion 200S2 in the vertical direction (e.g., the Z-direction).

In an example embodiment, the depth d2 may be greater than a thickness of the second upper insulating layer UI2 in the vertical direction.

The fourth portion 200S2 may be defined as including a plurality of portions 200S2_1 and 200S2_2. The plurality of portions 200S2_1 and 200S2_2 may include a first portion 200S2_1 and a second portion 200S2_2 connected to each other.

The first portion 200S2_1 may be a portion formed on a side surface of the second substrate 210, and the second portion 200S2_2 may be a portion formed on a side surface of the second upper insulating layer UI2. The first portion 200S2_1 may be a portion formed in the upper region of the side surface of the second substrate 210. A depth of the first portion 200S2_1 in the vertical direction (e.g., the Z-direction) may be substantially the same as or less than a depth of the second portion 200S2_2 in the vertical direction.

In another aspect, each of the plurality of second semiconductor chips C2 may be defined as including a plurality of inclination surfaces. Each of the plurality of second semiconductor chips C2 may include a first inclination surface formed in the lower region of the second side surface 200S, a second inclination surface connected to the first inclination surface and formed in the upper region of the side surface of the second substrate 210, and a third inclination surface connected to the second inclination surface and formed on the side surface of the second upper insulating layer UI2. Here, the first inclination may correspond to the third portion 200S1, the second inclination may correspond to the first portion 200S2_1 of the fourth portion 200S2, and the third inclination may correspond to the second portion 200S2_2 of the fourth portion 200S2. According to an example embodiment, the second and third inclinations may be referred to as curved surface portions. The magnitude of the absolute value of the mean inclination of the second inclination may be less than the magnitude of the absolute value of the mean inclination of the first inclination, and the magnitude of the absolute value of the mean inclination of the third inclination may be less than the magnitude of the absolute value of the mean inclination of the second inclination.

Referring to FIG. 5, an uppermost second-second semiconductor chip C2_2 may have a second side surface 200U extending from the edge of the lower surface of the second lower insulating layer LI2 to the edge of the upper surface of the second upper insulating layer UI2.

The second side surface 200U may be defined as including a plurality of portions 200U1 and 200U2. The plurality of portions 200U1 and 200U2 may include a fifth portion 200U1 and a sixth portion 200U2 connected to each other.

The fifth portion 200U1 may have a fifth lower end be5 connected to a lower surface of the second-second semiconductor chip C2_2, and a fifth upper end te5 connected to the sixth portion 200U2, and may extend from the fifth lower end be5 to the fifth upper end te5 at a constant fifth inclination. The fifth upper end te5 may be formed on the side surface of the second upper insulating layer UI2.

The sixth portion 200U2 may have a sixth lower end be6 connected to the fifth upper end te5, and a sixth upper end te6 connected to an upper surface of the second-second semiconductor chip C2_2, and may extend from the sixth lower end be6 to the sixth upper end te6 at a reduced sixth inclination. In another aspect, a magnitude of the absolute value of the sixth inclination may decrease from the sixth lower end be6 to the sixth upper end te6.

The magnitude of the absolute value of the average of the sixth inclination of the sixth portion 200U2 may be less than the magnitude of the absolute value of the average of the fifth inclination of the fifth portion 200U1. Here, the average of the fifth inclinations may be referred to as a fifth mean inclination, and the average of the sixth inclinations may be referred to as a sixth mean inclination. Here, each of the fifth and sixth mean inclinations may be defined as a ratio of a depth in the vertical direction (e.g., the Z-direction) to a width in the horizontal direction (e.g., the X-direction and/or the Y-direction). For example, the sixth mean inclination may be defined as a ratio of a depth d_u in the vertical direction to a width w_u in the horizontal direction.

In an example embodiment, the width w_u of the sixth portion 200U2 in the horizontal direction (e.g., X-direction and/or Y-direction) may be greater than the depth d_u in the vertical direction (e.g., Z-direction). The width w_u may be, for example, approximately 10 um or less. In an example embodiment, the width w1 may be, for example, approximately 5 um to approximately 10 um. The depth d_u may be, for example, approximately 1 um or less. In an example embodiment, the depth d_u may range, for example, from approximately 0.5 um to approximately 1 um.

In an example embodiment, the depth d_u may be less than the thickness of the second upper insulating layer UI2 in the vertical direction.

In another aspect, the second-second semiconductor chip C2_2 may be defined as including a plurality of inclination surfaces. The second-second semiconductor chip C2_2 may include a first inclination surface formed in a lower region of the side surface of the second upper insulating layer UI2 and in the side surface of the second substrate 210, and a second inclination surface connected to the first inclination surface and formed in an upper region of the side surface of the second upper insulating layer UI2. Here, the first inclination surface may correspond to the fifth portion 200U1, and the second inclination surface may correspond to the sixth portion 200U2. According to an example embodiment, the second inclination surface may be referred to as a curved surface portion. The magnitude of the absolute value of the mean inclination of the second inclination surface may be less than the magnitude of the absolute value of the mean inclination of the first inclination surface.

The third semiconductor chip C3 may be disposed on the second-second semiconductor chip C2_2, and may include a third substrate 310, a third circuit layer 320, a third lower insulating layer LI3, and front pads LP3 disposed on a front surface (e.g., bottom surface). The third substrate 310 the third circuit layer 320, the third lower insulating layer LI3, and the front pads LP3 have characteristics identical to or similar to the first substrate 110, the first circuit layer CL, the lower insulating layer (not illustrated), and the lower connection terminals LT, which are the corresponding elements of the base chip BC described above, and thus, redundant descriptions will be omitted.

Each of the front pads LP3 of a third semiconductor chip 300 may be in contact with a corresponding one of the second lower pads LP2 of the second-second semiconductor chip C2 adjacent to each other in the first direction. The third lower insulating layer LI3 of the third semiconductor chip 300 may be in contact with the second upper insulating layersUI2 of the second-second semiconductor chip C2 adjacent to each other in the first direction.

The third semiconductor chip 300 may have a front surface on which the front pads LP3 are disposed, a rear surface (e.g., top surface) opposite to the front surface, and a third side surface 300S extending from an edge of the front surface to an edge of the rear surface.

The third semiconductor chip C3 may be disposed at an uppermost side among the plurality of semiconductor chips C1, C2 and C3, and a rear surface thereof may be exposed from the encapsulant ML. Additionally, the third semiconductor chip C3 may have a thickness greater than a thickness of the first semiconductor chip C1 and a thickness of at least one of the second semiconductor chips C2.

The first substrate 110 of the first semiconductor chip C1 may have a first width CW1 in the horizontal direction. The second substrate 210 of at least one second semiconductor chip C2 may have a second width in the horizontal direction. The third substrate 310 of the third semiconductor chip C3 may have a third width CW3 in the horizontal direction. The third width CW3 may be smaller than the second width (e.g. CW2_1, CW2_2), and the second width may be smaller than the first width CW1.

When the at least one second semiconductor chip C2 includes a plurality of second semiconductor chips, a width of the second substrate 210 of each of the plurality of second semiconductor chips C2 in the horizontal direction may gradually decrease in the vertical direction (Z-direction). For example, a horizontal width CW2_1 of the lowermost second-first semiconductor chip C2_1 may be less than the first width CW1, a horizontal width CW2_2 of the uppermost second-second semiconductor chip C2_2 may be less than the horizontal width CW2_1 of the second-first semiconductor chip C2_1, and the third width CW3 may be less than the horizontal width CW2_1 of the second-first semiconductor chip C2_1 (see FIG. 2).

A ratio at which the horizontal widths (e.g., CW1, CW2_1, CW2_2 and CW3) decrease in the first direction (Z-direction) may gradually decrease in the first direction (see FIG. 1).

A magnitude of an absolute value of the mean inclination of an inclination surface (or curved surface portion) formed on edges of each of the first semiconductor chip C1 and at least one second semiconductor chip C2 may gradually increase in the vertical direction (Z-direction). For example, a magnitude of an absolute value of a fourth mean inclination of a second portion 200S_1 of the second-first semiconductor chip C2_1 may be greater than the magnitude of the absolute value of the second mean inclination of the second portion 100S2 of the first semiconductor chip C1. For example, a magnitude of an absolute value of a sixth mean inclination of the sixth portion 200U2 of a second-second semiconductor chip C2_2 may be greater than the magnitude of the absolute value of the fourth mean inclination of the second portion 200S_1 of the second-first semiconductor chip C2_1.

According to the above example embodiment of the present disclosure, an inclination surface may be formed on side surfaces of each edge of a plurality of semiconductor chips 100 and 200. This may be interpreted as being performed in a planarization process for surfaces of each of the semiconductor chips in order to remove the surface topology accumulated when the plurality of semiconductor chips 100 and 200 are stacked on the base chip BC.

A chip of a lower end (e.g., the first semiconductor chip C1) may be configured so that an inclination (e.g., the second inclination) of an inclination surface formed on an edge of the chip of the lower end may be formed to be gentler than an inclination (e.g., the fourth inclination) of an inclination surface formed on an edge of a chip of an upper end (e.g., the second-first semiconductor chip C2_1). This may be interpreted as being because the chip of the lower end receives relatively more mechanical stress as compared to the chip of the upper end.

Additionally, a horizontal width of the plurality of semiconductor chips 100 and 200 stacked on the base chip BC may decrease in the vertical direction. Accordingly, the bonding quality and/or reliability between edge portions of additionally stacked semiconductor chips may be improved.

The encapsulant ML may encapsulate a plurality of semiconductor chips C1, C2 and C3 on the base chip BC. The encapsulant ML may expose a rear surface of the third semiconductor chip C3. According to an example embodiment, the encapsulant ML may also cover the rear surface of the third semiconductor chip C3. The encapsulant ML may be formed of or include, for example, an insulating material such as Epoxy Mold Compound (EMC), but the material of the encapsulant ML is not particularly limited. The encapsulant ML may surround the side surfaces 100S, 200S and 300S of the plurality of semiconductor chips C1, C2 and C3. According to an example embodiment, a heat dissipation structure (not illustrated) may be disposed on an upper portion of the encapsulant ML. The heat dissipation structure (not illustrated) may control warpage of the semiconductor package 10, and may release heat generated from the plurality of semiconductor chips C1, C2 and C3 to the outside.

A width of the encapsulant ML in the horizontal direction may increase in the first direction (e.g., Z-direction), on at least one side of the semiconductor chip stack. In an example embodiment, the encapsulant ML may include a portion in which a width thereof in the horizontal direction increases in the first direction (e.g., Z-direction), on at least one side of the semiconductor chip stack. The portion of the encapsulant ML may include, for example, a portion in contact with the second portion 100S2 of the first side surface 100S of the first semiconductor chip C1, the fourth portion 200S2 of the second side surface 200S of the second-first semiconductor chip C2_1, and/or the sixth portion 200U2 of the second side surface 200U of the second-second semiconductor chip C2_2.

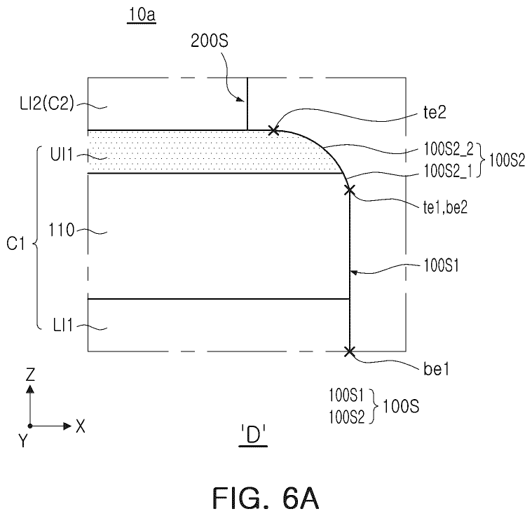

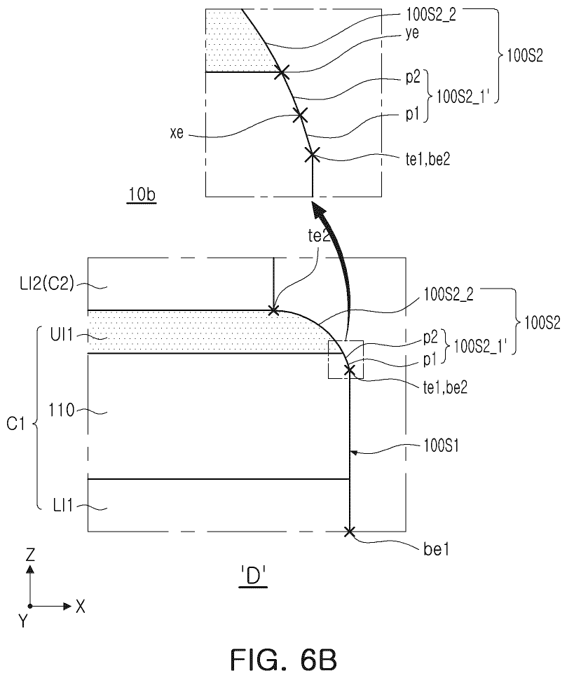

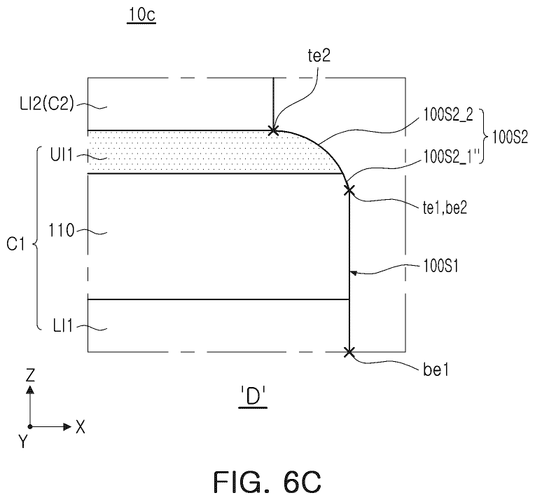

FIGS. 6A to 6C are enlarged views of a portion of a semiconductor package according to some example embodiments. FIGS. 6A to 6C are enlarged views of a portion of region ‘D’ of FIG. 4.

Referring to FIG. 6A, a semiconductor package 10a of an example embodiment may be identical to or similar to that described with reference to FIGS. 1 to 5, except that a side surface of a chip of an upper end (e.g., a second semiconductor chip C2) is spaced apart from an upper end of a chip of a lower end (e.g., a first semiconductor chip C1) in a horizontal direction (e.g., X-direction).

A second side surface 200S of the second semiconductor chip C2 may be spaced apart from an upper end te2 of the first semiconductor chip C1 in the horizontal direction (e.g., X-direction). For example, the second side 200S of the second-first semiconductor chip C2_1 may be spaced apart from the upper end te2 of the first semiconductor chip C1 in the horizontal direction (e.g., X-direction). Similarly, the third side 300S of the third semiconductor chip C3 may be spaced apart from the upper end of the second-second semiconductor chip C2_2 in the horizontal direction (e.g., X-direction).

Referring to FIGS. 6B and 6C, semiconductor packages 10b and 10c of some example embodiments may be substantially identical to or similar to that described with reference to FIGS. 1 to 6A, except that at least a portion of the second portion 100S2 includes a portion having a constant inclination.

Referring to FIG. 6B, in the semiconductor package 10b of an example embodiment, a first portion 100S2_1′ of the second portion 100S2 may include a first region p1 including a surface having a constant inclination from a first upper end te1 of the first portion 100S1 to a lower end xe of a second region p2 (or the upper end xe of the first region p1), and the second region p2 including a surface having a reduced inclination from an upper end xe of the first region p1 to a lower end ye of the second portion 100S2_2.

Referring to FIG. 6C, in a semiconductor package 10c of an example embodiment, a first portion 100S2_1″ of the second portion 100S2 may be a surface having a constant inclination from the first upper end te1 of the first portion 100S1 to a lower end of the second portion 100S2_2.

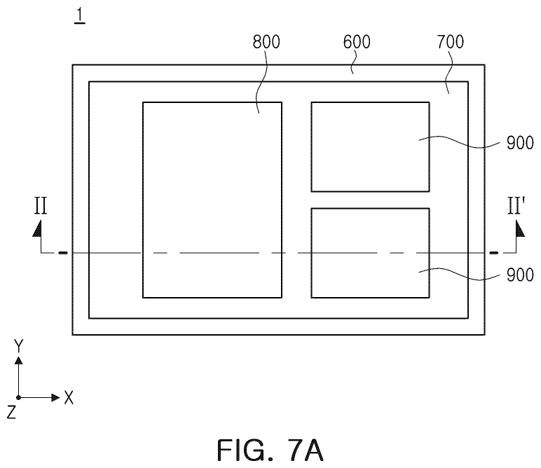

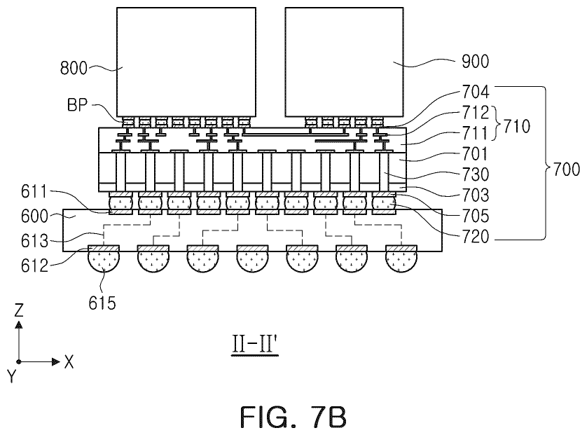

FIG. 7A is a plan view illustrating a semiconductor package according to an example embodiment.

FIG. 7B is a cross-sectional view illustrating a semiconductor package along line II-II′ of FIG. 7A.

Referring to FIGS. 7A and 7B, a semiconductor package 1 of an example embodiment may include a package substrate 600, an interposer substrate 700, a first chip structure 800, and a second chip structure 900.

The first chip structure 800 may include a logic chip such as a central processor (CPU), a graphics processor (GPU), a field programmable gate array (FPGA), a digital signal processor, an encryption processor, a microprocessor, a microcontroller, an analog-to-digital converter, or an ASIC.

The second chip structure 900 may be a semiconductor package structure having the characteristics identical to or similar to the semiconductor packages 10, 10a, 10b and 10c described above with reference to FIGS. 1 to 6C. For example, the second chip structure 900 may include a high-capacity memory device such as a high bandwidth memory (HBM).

The package substrate 600 is a support substrate on which the interposer substrate 700 is mounted, and may be a semiconductor package substrate including a printed circuit board (PCB), a ceramic substrate, a glass substrate, and a tape interconnection substrate. The package substrate 600 may include a lower pad 612, an upper pad 611, and an interconnection circuit 613. An external connection bump 615 connected to the lower pad 612 may be disposed on a lower surface of the package substrate 600. The external connection bump 615 may include, for example, a solder ball.

The interposer substrate 700 may include a semiconductor substrate 701, a lower protection layer 703, a lower pad 705, an interconnect structure 710, a conductive bump 720, and a through-silicon electrode 730. The first chip structure 800 and the second chip structure 900 may be electrically connected to each other via the interposer substrate 700.

The semiconductor substrate 701 may be formed of, for example, any one of a silicon, organic, plastic, and glass substrate. When the semiconductor substrate 701 is a silicon substrate, the interposer substrate 700 may be referred to as a silicon interposer. Unlike what is illustrated in the drawing, when the semiconductor substrate 701 is an organic substrate, the interposer substrate 700 may be referred to as a panel interposer.

The lower protection layer 703 may be disposed on a lower surface of the semiconductor substrate 701, and the lower pad 705 may be disposed below the lower protection layer 703. The lower pad 705 may be connected to a through-silicon electrode 730. The interposer substrate 700 may be electrically connected to the package substrate 600 through conductive bumps 720 disposed below the lower pad 705.

The interconnect structure 710 may be disposed on an upper surface of the semiconductor substrate 701, and may include an interlayer insulating layer 711 and a single-layer or multilayer interconnection structure 712. When the interconnect structure 710 is formed of a multilayer interconnection structure, the interconnection patterns of different layers may be connected to each other through contact vias. The first semiconductor chip structure 800 and the second semiconductor chip structure 900 may be electrically connected to an upper pad 704 through the connection bumps BP.

The through-silicon electrode 730 may extend from the upper surface of the semiconductor substrate 701 to a lower surface thereof. Additionally, the through-silicon electrode 730 may extend into the interior of the interconnect structure 710, and may thus be electrically connected to the multilayer interconnection structure 712. According to an example embodiment, the interposer substrate 700 may include only an interconnect structure therein, and may not include the through-silicon electrode 730.

The interposer substrate 700 may be used for the purpose of converting or transmitting an input electrical signal between the package substrate 600 and the first chip structure 800 or the second chip structure 900. Accordingly, the interposer substrate 700 may not include devices such as active devices or passive devices. Additionally, according to an example embodiment, the interconnect structure 710 may be disposed below the through-silicon electrode 730. For example, a positional relationship between the interconnect structure 710 and the through-silicon electrode 730 may be relative.

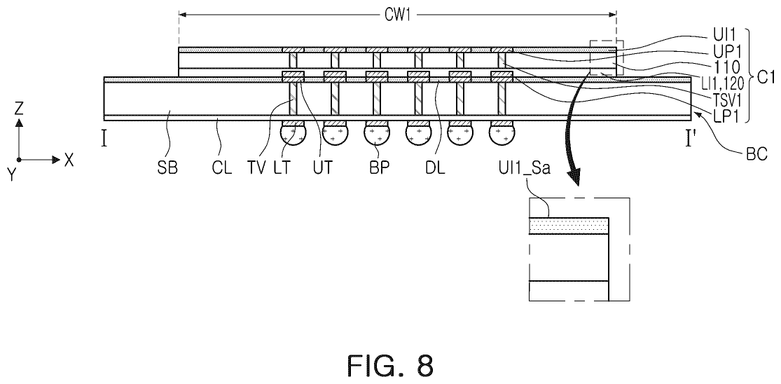

FIGS. 8 to 12 are cross-sectional views illustrating a method of manufacturing a semiconductor package according to an example embodiment, according to a process order.

Referring to FIG. 8, a first semiconductor chip C1 may be formed on a base chip BC.

The base chip BC including a substrate SB, a circuit layer CL, lower connection terminals LT and upper connection terminals UT opposite to each other, an upper protection layer DL surrounding a side surface of each of the upper connection terminals UT on the substrate SB, and through-vias LT electrically connecting the lower connection terminals LT and the upper connection terminals UT may be provided. A plurality of connection bumps BP may be attached to a lower portion of the base chip BC. The base chip BC may be temporarily attached to a carrier (not illustrated) by an adhesive material layer (not illustrated).

The first semiconductor chip C1 may be formed on the base chip BC. The first semiconductor chip C1 may be understood as including the components described with reference to FIGS. 1 to 5. The first semiconductor chip C1 may be directly bonded to the base chip BC by intermetallic bonding and inter-dielectric bonding (hereinafter referred to as “direct bonding”) without a conductive member (e.g., solder bump, copper pillar, or the like.) for an electrical connection.

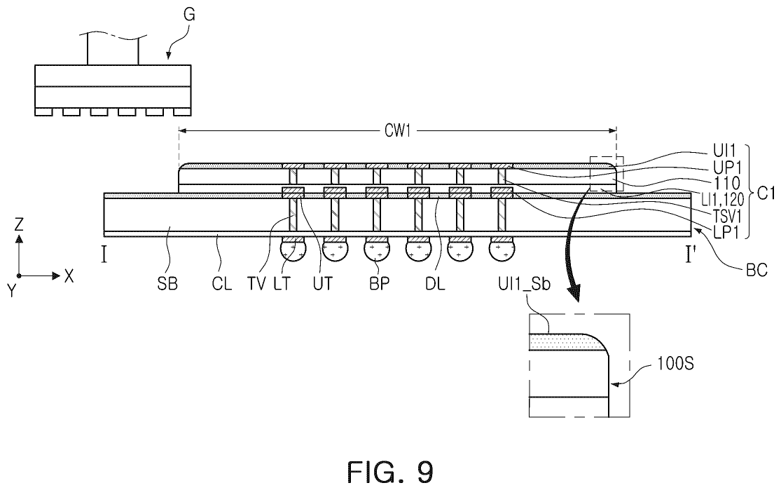

Referring to FIG. 9, a planarization process may be applied to the first semiconductor chip C1.

The planarization process may include a grinding process and a polishing process. For example, a portion of an upper surface (‘UI1_Sa’ in FIG. 8) of the first semiconductor chip C1 may be removed using a flattening device G such as a grinding wheel or a polishing pad, thus forming a flat surface UI1_Sb provided for ‘direct bonding.’

Accordingly, the upper surface (‘UI1_Sa’ in FIG. 8) of the first semiconductor chip C1 before performing the planarization process may be a wave surface having high and low portions (or a plurality of raised portions), and the upper surface UI1_Sb of the first semiconductor chip C1 after performing the planarization process may be a flat surface. Surface roughness of the upper surface UI1_Sb of the first semiconductor chip C1 may be approximately 0.5 Å or less, for example, in the range of approximately 0.1 Å to approximately 0.5 Å.

By the planarization process, the first semiconductor chip C1 may have an inclination surface in which an inclination thereof changes constantly on an edge thereof (see FIG. 4).

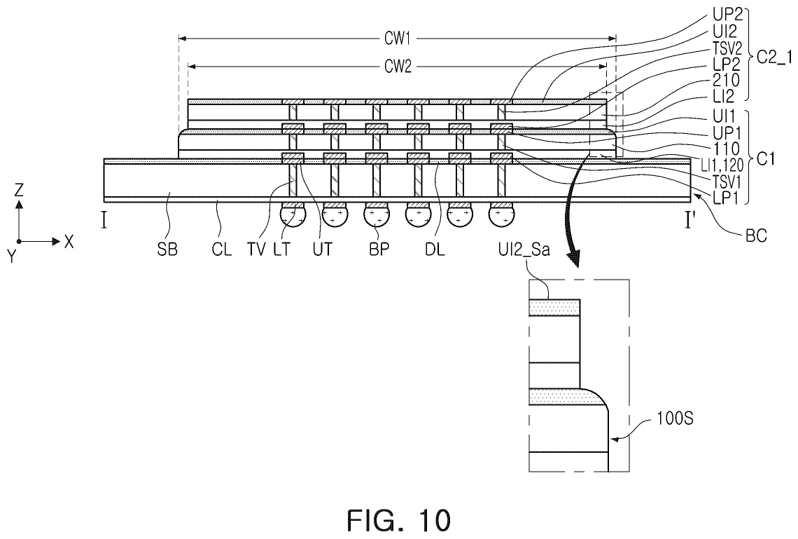

Referring to FIG. 10, at least one second semiconductor chip C2 may be formed on the first semiconductor chip C1.

At least one second semiconductor chip C2 may be formed on the first semiconductor chip C1. The at least one second semiconductor chip C2 may be understood as including the components described with reference to FIGS. 1 to 5. At least one second semiconductor chip C2 may be directly bonded to the first semiconductor chip C1 by intermetallic bonding and inter-dielectric bonding (hereinafter referred to as ‘direct bonding’) without a conductive member (e.g., solder bump, copper pillar, or the like) for electrical connection.

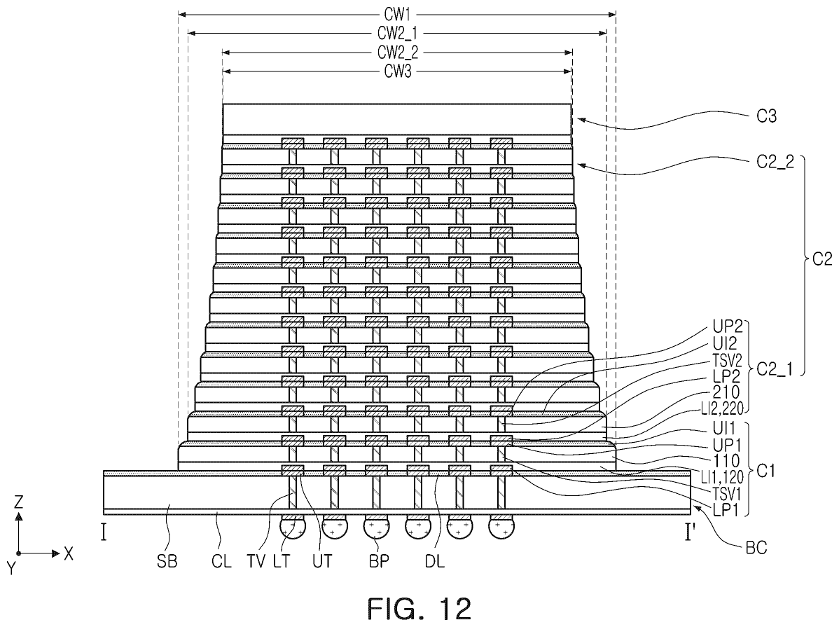

When a plurality of second semiconductor chips C2 are provided, the second-first semiconductor chip C2_1 may be understood as being formed on the first semiconductor chip C1. A width CW2_1 of the second-first semiconductor chip C2_1 in the horizontal direction may be less than a width CW1 of the first semiconductor chip C1 in the horizontal direction as illustrated in FIG. 12. The side surface (‘200S’ in FIG. 4) of the second-first semiconductor chip C2_1 may be formed so as to be aligned with the second upper end te2 of the side surface (100S2 in FIG. 4) of the first semiconductor chip C1.

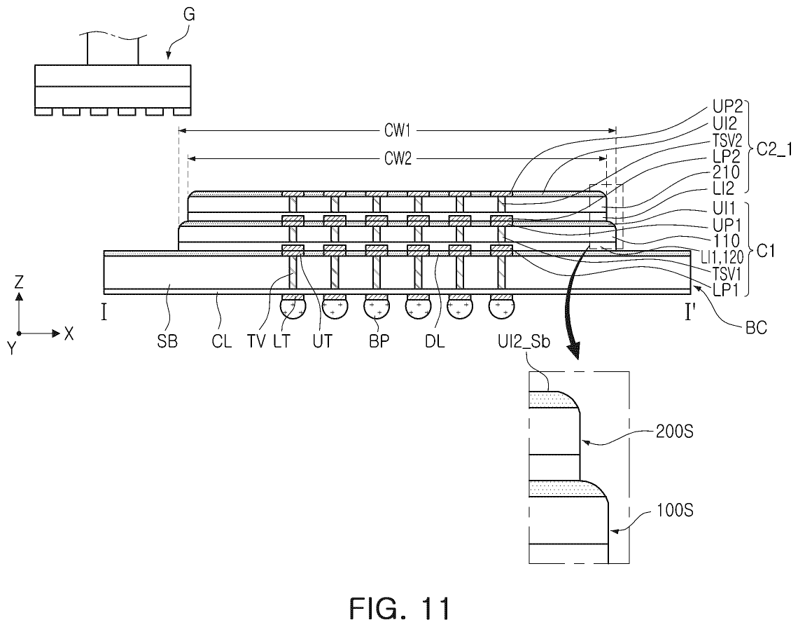

Referring to FIG. 11, a planarization process may be applied to at least one second semiconductor chip C2.

The planarization process may be applied to at least one second semiconductor chip C2. When a plurality of second semiconductor chips C2 are provided, the planarization process may be understood as being applied to the lowermost second-first semiconductor chip C2_1. Similar to that described with reference to FIG. 10, a portion of the upper surface (‘UI2_Sa’ in FIG. 10) of the second-first semiconductor chip C2_1 may be removed, thus forming a flat surface UI2_Sb provided for ‘direct bonding.’

Accordingly, the upper surface (‘UI2_Sa’ in FIG. 10) of the second-first semiconductor chip C2_1 before performing the planarization process may be a wave surface having high and low heights (or a plurality of raised portions), and an upper surface UI2_Sb of the second-first semiconductor chip C2_1 after performing the planarization process may be a flat surface. Surface roughness of the upper surface UI2_Sb of the second-first semiconductor chip C2_1 may be approximately 0.5 Å or less, for example, in a range of approximately 0.1 Å to approximately 0.5 Å.

By the planarization process, the second-first semiconductor chip C2_1 may have an inclination surface in which an inclination thereof changes constantly on an edge thereof (see FIG. 4).

Referring to FIG. 12, a plurality of second semiconductor chips C2 including an uppermost second-second semiconductor chip C2_2 may be sequentially formed on a lowermost second-first semiconductor chip C2_1, and the planarization process may be applied to the plurality of second semiconductor chips C2. Then, a third semiconductor chip C3 may be formed on the uppermost second-second semiconductor chip C2_2.

A plurality of second semiconductor chips C2 including the uppermost second-second semiconductor chip C2_2 may be sequentially formed on the lowermost second-first semiconductor chip C2_1. Each of the plurality of second semiconductor chips C2 may be directly bonded to each of the plurality of second semiconductor chips C2 adjacent to each other in the vertical direction by intermetallic bonding and inter-dielectric bonding (hereinafter referred to as ‘direct bonding’) without a conductive member (e.g., solder bump, copper pillar, or the like) for electrical connection.

Similarly to that described with reference to FIGS. 8 and 10, the planarization process may be applied to each of the plurality of second semiconductor chips C2.

Then, a third semiconductor chip C3 may be formed on the uppermost second-2 semiconductor chip C2_2. The third semiconductor chip C3 may be understood as including the components described with reference to FIGS. 1 to 5.

Then, an encapsulant ML covering the plurality of semiconductor chips 100, 200 and 300 may be formed on the base chip BC. Next, the semiconductor package 10 may be provided through a sawing process of cutting the base chip BC in the vertical direction.

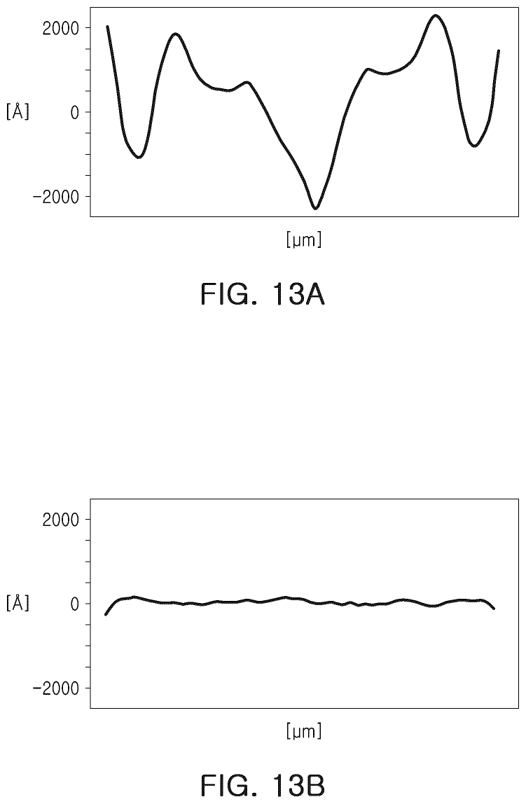

FIGS. 13A and 13B are graphs illustrating surface topologies of each of a plurality of semiconductor chips 100 and 200 before and after a planarization process. FIGS. 13A and 13B illustrate results of scanning the surface topologies of each of a plurality of semiconductor chips 100 and 200 before and after the planarization process using Atomic Force Microscope (AFM). FIG. 13A may illustrate a topology of the surface UI1_Sa of FIG. 8 or UI2_Sa of FIG. 10, and FIG. 13B may illustrate a topology of the surface UI1_Sb of FIG. 9 or UI2_Sb of FIG. 11.

Referring to FIGS. 13A and 13B, upper surfaces (e.g., UI1_Sa of FIG. 8 and UI2_Sa of FIG. 10) of each of the plurality of semiconductor chips 100 and 200 before the planarization process has topology characteristics in which a difference in height of a surface curvature is relatively large. For example, a difference between the highest point and the lowest point on each of the upper surfaces thereof may be approximately 4,000 Å or more. This is merely an example value defining surface topology characteristics in which the bonding quality of direct bonding may be degraded, and example embodiments of the present disclosure are not applied only to the above-described numerical range.

Upper surfaces (e.g., UI1_Sb of FIG. 9 and UI2_Sb of FIG. 11) of each of the plurality of semiconductor chips 100 and 200 after the planarization process may be a flat surface from which the surface topology is reduced or removed. Accordingly, the difference between the highest point and the lowest point on each of the upper surfaces thereof may be approximately 10 Å or less. However, this is merely an example, and the difference between the highest and lowest points on each of the upper surfaces may be substantially close to 0.

The present disclosure is not limited to the above-described example embodiments and the accompanying drawings but is defined by the appended claims. Therefore, those of ordinary skill in the art may make various replacements, modifications, or changes, and combinations of some example embodiments without departing from the scope of the present disclosure defined by the appended claims, and these replacements, modifications, or changes should be construed as being included in the scope of the present disclosure.

What is claimed is:

1. A semiconductor package, comprising:
a base chip including lower connection terminals, upper connection terminals and through-electrodes, the lower connection terminals and upper connection terminals being opposite to each other, the through-electrodes electrically connecting the lower connection terminals and the upper connection terminals; and
a semiconductor chip stack including a plurality of semiconductor chips sequentially stacked on the base chip in a first direction, wherein
the plurality of semiconductor chips of the semiconductor chip stack comprises
a first semiconductor chip on the base chip, the first semiconductor chip including first lower pads, first upper pads and first through-vias, the first lower pads and the first upper pads being opposite to each other, the first through-vias electrically connecting the first lower pads and the first upper pads, and
at least one second semiconductor chip on the first semiconductor chip, the at least one second semiconductor chip including second lower pads, second upper pads and second through-vias, the second lower pads and the second upper pads being opposite to each other, the second through-vias electrically connecting the second lower pads and the second upper pads,
a plurality of connection bumps below the base chip and electrically connected to the lower connection terminals,
the first lower pads of the first semiconductor chip are in contact with corresponding ones of the upper connection terminals of the base chip that are adjacent to the first lower pads of the first semiconductor chip in the first direction, respectively,
the first upper pads of the first semiconductor chip are in contact with corresponding ones of the second lower pads of the at least one second semiconductor chip that are adjacent to the first upper pads of the first semiconductor chip in the first direction, respectively, and
a side surface of the first semiconductor chip comprises
a first portion extending from a lower surface of the first semiconductor chip at a first inclination,
a second portion extending from the first portion to an upper surface of the first semiconductor chip at a second inclination less than the first inclination,
a side surface of the at least one second semiconductor chip comprises
a third portion extending from a lower surface of the at least one second semiconductor chip at a third inclination, and
a fourth portion extending from the third portion to an upper surface of the at least one second semiconductor chip at a fourth inclination less than the third inclination.

2. The semiconductor package of claim 1, wherein
the first portion has a first lower end connected to the lower surface of the first semiconductor chip, and a first upper end connected to the second portion, and
the first inclination is constant from the first lower end to the first upper end.

3. The semiconductor package of claim 2, wherein
the second portion has a second lower end connected to the first upper end of the first portion, and a second upper end connected to the upper surface of the at least one second semiconductor chip, and
a magnitude of an absolute value of the second inclination decreases from the second lower end to the second upper end.

4. The semiconductor package of claim 3, wherein
a width of the second portion in a horizontal direction is greater than a length of the second portion in the first direction.

5. The semiconductor package of claim 3, wherein
a width of the second portion in a horizontal direction ranges from 300 um to 400 um, and
a length of the second portion in the first direction ranges from 1 um to 10 um.

6. The semiconductor package of claim 3, wherein
a side surface of the at least one second semiconductor chip is spaced apart from the second upper end of the second portion.

7. The semiconductor package of claim 1, wherein
the third portion has a third lower end connected to the lower surface of the at least one second semiconductor chip and a third upper end connected to the fourth portion, and
the third inclination is constant from the third lower end to the third upper end.

8. The semiconductor package of claim 7, wherein
the fourth portion has a fourth lower end connected to the third upper end of the third portion and a fourth upper end connected to the upper surface of the at least one second semiconductor chip, and
a magnitude of an absolute value of the fourth inclination decreases from the third lower end to the third upper end.

9. The semiconductor package of claim 8, wherein
a width of the fourth portion in a horizontal direction is greater than a length of the fourth portion in the first direction.

10. The semiconductor package of claim 1, wherein
a magnitude of an absolute value of an average of the fourth inclination is greater than a magnitude of an absolute value of an average of the second inclination.

11. The semiconductor package of claim 1, further comprising:
a third semiconductor chip on the at least one second semiconductor chip, the third semiconductor chip including front pads on a front surface thereof,
wherein the front pads of the third semiconductor chip are in contact with corresponding ones of the second upper pads of the at least one second semiconductor chip that are adjacent to the front pads of the third semiconductor chip in the first direction, respectively.

12. The semiconductor package of claim 1, wherein
a surface roughness of each of the upper surface of the first semiconductor chip and the upper surface of the at least one second semiconductor chip is in a range of 0.5 Å or less.

13. A semiconductor package, comprising:
a base chip including lower connection terminals, upper connection terminals and through-electrodes, the lower connection terminals and the upper connection terminals being opposite to each other, the through-electrodes electrically connecting the lower connection terminals and the upper connection terminals;
a first semiconductor chip on the base chip, the first semiconductor chip including a first semiconductor substrate, first lower pads, first upper pads, a first passivation layer and first through-vias, the first lower pads in a lower portion of the first semiconductor substrate, the first upper pads in an upper portion of the first semiconductor substrate, the first passivation layer surrounding the first upper pads in the upper portion of the first semiconductor substrate, the first through-vias penetrating through the first semiconductor substrate and electrically connecting the first lower pads and the first upper pads;
a plurality of second semiconductor chips sequentially stacked on the first semiconductor chip in a first direction, each of the plurality of second semiconductor chips including a second semiconductor substrate, second lower pads, second upper pads, a second passivation layer and second through-vias, the second lower pads in a lower portion of the second semiconductor substrate, the second upper pads in an upper portion of the second semiconductor substrate, the second passivation layer surrounding the second upper pads in the upper portion of the second semiconductor substrate, the second through-vias penetrating through the second semiconductor substrate and electrically connecting the second lower pads and the second upper pads; and
a plurality of connection bumps below the base chip and electrically connected to the lower connection terminals, wherein
the first lower pads of the first semiconductor chip are in contact with corresponding ones of the upper connection terminals of the base chip, respectively,
the first upper pads of the first semiconductor chip are in contact with corresponding ones of the second lower pads of a second semiconductor chip that is adjacent to the first semiconductor chip in the first direction, among the plurality of second semiconductor chips, respectively,
the second upper pads of each of the plurality of second semiconductor chips are in contact with corresponding ones of the second lower pads of an adjacent second semiconductor chip, among the plurality of second semiconductor chips, in the first direction, respectively,
a width of the first semiconductor substrate of the first semiconductor chip in a horizontal direction is greater than a width of the second semiconductor substrate of the each of the plurality of second semiconductor chips in the horizontal direction, and
the second semiconductor substrate of the each of the plurality of second semiconductor chips has a width in the horizontal direction that decreases as the second semiconductor substrate being away from the base chip in the first direction.

14. The semiconductor package of claim 13, wherein
the first semiconductor chip comprises
a first inclination surface on a side surface of a lower region of the first semiconductor substrate,
a second inclination surface connected to the first inclination surface and being on a side surface of an upper region of the first semiconductor substrate, and
a third inclination surface connected to the second inclination surface and being on a side surface of the first passivation layer.

15. The semiconductor package of claim 14, wherein
an inclination of the second inclination surface is less than an inclination of the first inclination surface, and
an inclination of the third inclination surface is less than the inclination of the second inclination surface.

16. The semiconductor package of claim 14, wherein
at least a portion of the second inclination surface includes a portion having a constant inclination.

17. The semiconductor package of claim 13, wherein
the plurality of second semiconductor chips include a lowermost second-first semiconductor chip of the plurality of second semiconductor chips and an uppermost second-second semiconductor chip of the plurality of second semiconductor chips, and
the lowermost second-first semiconductor chip includes a first curved surface portion, the first curved surface portion being on a side surface of an upper region of the second semiconductor substrate and a side surface of the second passivation layer.

18. The semiconductor package of claim 17, wherein
the uppermost second-second semiconductor chip includes a second curved surface portion, the second curved surface portion being on a side surface of an upper region of the second passivation layer, and
a length of the second curved surface portion in the first direction is less than a length of the second passivation layer of the second-second semiconductor chip in the first direction.

19. A semiconductor package, comprising:
a base chip including lower connection terminals, upper connection terminals and through-electrodes, the lower connection terminals and the upper connection terminals being opposite to each other, the through-electrodes electrically connecting the lower connection terminals and the upper connection terminals; and
a semiconductor chip stack including a plurality of semiconductor chips sequentially stacked on the base chip in a first direction, wherein
the plurality of semiconductor chips of the semiconductor chip stack comprises
a first semiconductor chip on the base chip, the first semiconductor chip including first lower pads, first upper pads and first through-vias, the first lower pads and first upper pads being opposite to each other, the first through-vias electrically connecting the first lower pads and the first upper pads, and
a plurality of second semiconductor chips sequentially stacked on the first semiconductor chip in the first direction, each of the plurality of second semiconductor chips including second lower pads, second upper pads and second through-vias, the second lower pads and second upper pads being opposite to each other, the second through-vias electrically connecting the second lower pads and the second upper pads,
a plurality of connection bumps below the base chip and electrically connected to the lower connection terminals,
an encapsulant covering a side surface of the first semiconductor chip and side surfaces of the each of the plurality of second semiconductor chips on the base chip, and
on at least one side of the semiconductor chip stack, the encapsulant includes a portion in which a width thereof in a horizontal direction increases as the encapsulant being away from the base chip in the first direction.

20. The semiconductor package of claim 19, wherein
the portion of the encapsulant is on at least one of a side portion of an upper region of the first semiconductor chip or a side portion of an upper region of at least one of the plurality of second semiconductor chips.
